(19) United States
(12) Patent Application Publication
(10) Pub. No.: US 2018/0366304 A1
(43) Pub. Date: Dec. 20, 2018

(54) PLASMA PROCESSING APPARATUS AND METHOD FOR FABRICATING SEMICONDUCTOR DEVICE USING THE SAME

(71) Applicant: SAMSUNG ELECTRONICS CO., LTD., Suwon-si (KR)

(72) Inventors: Seung Bo SHIM, Seoul (KR); Nam Jun KANG, Bucheon-si (KR); Se Kwon NA, Seoul (KR); Je-Hun WOO, Suwon-si (KR); Seung Kyu LIM, Seoul (KR); Ji Soo IM, Seongnam-si (KR)

(73) Assignee: SAMSUNG ELECTRONICS CO., LTD., Suwon-si (KR)

(21) Appl. No.: 15/867,188

(22) Filed: Jan. 10, 2018

(30) Foreign Application Priority Data
Jun. 14, 2017 (KR) 10-2017-0075074

(51) Int. Cl. H01J 37/32; H01L 21/67

(52) U.S. Cl. CPC H01J 37/32642; H01L 21/67069; H01J 2237/3344; H01J 37/3244; H01J 2237/002; H01J 37/32715

(57) ABSTRACT

A plasma processing apparatus and a method for fabricating a semiconductor device using the same are provided. The plasma processing apparatus includes: a chuck stage configured to support a wafer thereon; a dielectric ring configured to surround a periphery of the chuck stage, the dielectric ring including a paraelectric material; and a dielectric constant controller configured to control a dielectric constant of the dielectric ring.

### CROSS-REFERENCE TO RELATED APPLICATION

This application claims priority from Korean Patent Application No. 10-2017-0075074, filed on Jun. 14, 2017 in the Korean Intellectual Property Office, the contents of which in their entirety are herein incorporated by reference.

### BACKGROUND

### 1. Technical Field

Apparatuses and methods consistent with one or more exemplary embodiments relate to a plasma processing apparatus and a method for fabricating a semiconductor device using the same.

### 2. Description of the Related Art

Recent semiconductor processes are increasingly required to control a plasma for a high aspect ratio contact (HARC) process. In a related art, a method of increasing an etch rate by lowering a bias frequency and increasing radio frequency (RF) power to maximize the ion energy has been used.

However, as the aspect ratio increases, the effect of lowering the frequency and increasing the RF power decreases due to an increase of a loading effect.

In order to solve this problem, charging relaxation is promoted through an RF pulse to improve the loading effect, thereby improving the etch rate and profile shape. In this method, the charging effect is increased due to an increase in bias voltage resulting from an increase in RF power, which may have limitations.

### SUMMARY

Aspects of one or more exemplary embodiments provide a plasma processing apparatus with improved operating performance.

Aspects of one or more exemplary embodiments also provide a method for fabricating a semiconductor device using a plasma processing apparatus with improved operating performance.

However, aspects of the present disclosure are not restricted to those set forth herein. The above and/or other aspects will become more apparent to one of ordinary skill in the art to which the present disclosure pertains by referencing the detailed description of exemplary embodiments given below.

According to an aspect of an exemplary embodiment, there is provided a plasma processing apparatus including: a chuck stage configured to support a wafer thereon; a dielectric ring configured to surround a periphery of the chuck stage, the dielectric ring including a paraelectric material; and a dielectric constant controller configured to control a dielectric constant of the dielectric ring.

The dielectric constant controller may be configured to control the dielectric constant of the dielectric ring by applying a DC voltage to the dielectric ring and adjusting a magnitude of the applied DC voltage.

The dielectric constant controller may be configured to control the dielectric constant of the dielectric ring by applying an AC voltage to the dielectric ring and adjusting a frequency of the applied AC voltage.

The dielectric constant controller may be configured to control the dielectric constant of the dielectric ring by applying heat to the dielectric ring to adjust a temperature of the dielectric ring.

The plasma processing apparatus may further include a gas feeder configured to inject a gas onto the chuck stage.

One of the gas feeder and the chuck stage may be grounded, and the other one of the gas feeder and the chuck stage may be connected to an RF power source.

The dielectric ring may include an inner dielectric ring having the dielectric constant controlled by the dielectric constant controller, and an outer dielectric ring configured to surround the inner dielectric ring.

The inner dielectric ring may include the paraelectric material; and the outer dielectric ring may include at least one of aluminum oxide (Al₂O₃), aluminum nitride (AlN), polyethylene terephthalate (PETE), and polyetheretherketone (PEEK).

The paraelectric material may be at least one of barium titanate (BaTiO₃, bismuth ferrite (BiFeO₃), and barium strontium titanate (BST).

A temperature of the dielectric ring may be equal to or greater than a Curie temperature of the paraelectric material.

According to an aspect of another exemplary embodiment, there is provided a plasma processing apparatus including: a chamber including a sidewall; a chuck stage in the chamber and configured to support a wafer thereon; a gas feeder in the chamber and configured to supply a gas onto the chuck stage; a dielectric ring in the chamber and configured to surround the chuck stage or the gas feeder, the dielectric ring including a paraelectric material; and a dielectric constant controller configured to control a dielectric constant of the dielectric ring.

The dielectric ring may surround a side surface of the chuck stage.

The chuck stage may include a lower portion having a first diameter, and an upper portion having a second diameter smaller than the first diameter.

The dielectric ring may be in contact with a side surface of the lower portion of the chuck stage.

The dielectric ring may be in contact with a side surface of the upper portion of the chuck stage.

The plasma processing apparatus may further include a focus ring on the dielectric ring, the focus ring being in contact with the upper portion of the chuck stage and a side surface of the wafer.

The dielectric ring may be a part of the sidewall of the chamber.

The dielectric ring may surround a side surface of the gas feeder.

According to an aspect of another exemplary embodiment, there is provided a plasma processing apparatus including: a chamber including a cavity therein; a chuck stage in the chamber, the chuck stage configured to support a wafer thereon and to which RF power is applied; a gas feeder in the chamber and configured to supply a gas onto an upper surface of the chuck stage, the gas feeder being grounded; a first ring configured to surround the chuck stage; a second ring configured to surround the gas feeder; a third ring configured to surround the cavity, as a part of a sidewall of the chamber; and a dielectric constant controller configured to control a dielectric constant of at least one of the first ring, the second ring, and the third ring.

The plasma processing may further include a gas source connected to the gas feeder and configured to provide the gas used for a plasma.

The chamber may further include an opening through which the wafer enters and exits the chamber.

The plasma processing apparatus may further include a vacuum module, wherein the chamber further includes an outlet for discharging the gas used for a plasma, and wherein the vacuum module may be connected to the outlet to suck the gas used for the plasma through the outlet.

According to an aspect of another exemplary embodiment, there is provided a method for fabricating a semiconductor device, the method including: loading a wafer on a chuck stage located in a chamber; supplying a gas to the chamber; applying a bias voltage to the chamber to generate a plasma from the gas; and performing a plasma process using the plasma, wherein the performing the plasma process includes detecting a plasma incidence angle of an edge region of the wafer, and adjusting the detected plasma incidence angle.

According to an aspect of another exemplary embodiment, there is provided a method for fabricating a semiconductor device, the method including: controlling to supply a gas to a chamber in which a wafer is loaded on a chuck stage; controlling to apply a bias voltage to the chamber to generate a plasma from the gas; and controlling to perform a plasma process using the plasma, wherein the controlling to perform the plasma process includes controlling to detect a plasma incidence angle of an edge region of the wafer, and controlling to adjust the detected plasma incidence angle.

The controlling to adjust the detected plasma incidence angle may include controlling to adjust at least one of a temperature, a voltage magnitude of the applied bias voltage, and a frequency of the applied bias voltage.

The controlling to adjust the detected plasma incidence angle may include controlling a dielectric constant of a dielectric ring surrounding the chuck stage by applying a DC voltage to the dielectric ring and adjusting a magnitude of the applied DC voltage.

The controlling to adjust the detected plasma incidence angle may include controlling a dielectric constant of a dielectric ring surrounding the chuck stage by applying an AC voltage to the dielectric ring and adjusting a frequency of the applied AC voltage.

The controlling to adjust the detected plasma incidence angle may include controlling a dielectric constant of a dielectric ring surrounding the chuck stage by applying heat to the dielectric ring to adjust a temperature of the dielectric ring.

According to an aspect of another exemplary embodiment, there is provided a non-transitory computer-readable recording medium having recorded thereon a program executable by a computer for performing the method.

### BRIEF DESCRIPTION OF THE DRAWINGS

The above and/or other aspects and features will become more apparent by describing in detail exemplary embodiments with reference to the attached drawings, in which:

FIG. 1 is a conceptual view illustrating a plasma processing apparatus according to one or more exemplary embodiments;

FIG. 2 is a view illustrating an incident direction of a plasma of portion A in the plasma processing apparatus of FIG. 1;

FIG. 3 is a plan view illustrating in detail a second dielectric ring of FIG. 1;

FIG. 4 is a plan view illustrating in detail a chuck stage of FIG. 1;

FIG. 5 is a graph for explaining a change in dielectric constant of a material of the dielectric ring of FIG. 1 according to the temperature;

FIG. 6 is a graph for explaining a change in dielectric constant of the material of the dielectric ring of FIG. 1 according to the frequency;

FIG. 7 is a graph for explaining a change in dielectric constant of the material of the dielectric ring of FIG. 1 according to the voltage;

FIG. 8 is a conceptual diagram illustrating a plasma processing apparatus according to one or more exemplary embodiments;

FIG. 9 is a conceptual diagram illustrating a plasma processing apparatus according to one or more exemplary embodiments;

FIG. 10 is a conceptual diagram illustrating a plasma processing apparatus according to one or more exemplary embodiments;

FIG. 11 is a conceptual diagram illustrating a plasma processing apparatus according to one or more exemplary embodiments;

FIG. 12 is a conceptual diagram illustrating a plasma processing apparatus according to one or more exemplary embodiments;

FIG. 13 is a diagram for comparing etch rates of a plasma processing apparatus according to one or more exemplary embodiments;

FIG. 14 is a conceptual diagram illustrating a plasma processing apparatus according to one or more exemplary embodiments;

FIG. 15 is a conceptual diagram illustrating a plasma processing apparatus according to one or more exemplary embodiments;

FIG. 16 is a conceptual diagram illustrating in detail a dielectric constant controller of a plasma processing apparatus according to one or more exemplary embodiments;

FIG. 17 is a conceptual diagram illustrating in detail a dielectric constant controller of a plasma processing apparatus according to one or more exemplary embodiments;

FIG. 18 is a conceptual diagram illustrating in detail a dielectric constant controller of a plasma processing apparatus according to one or more exemplary embodiments;

FIG. 19 is a conceptual diagram illustrating in detail a dielectric constant controller of a plasma processing apparatus according to one or more exemplary embodiments;

FIG. 20 is a conceptual diagram illustrating in detail a dielectric constant controller of a plasma processing apparatus according to one or more exemplary embodiments;

FIG. 21 is a flowchart illustrating a method for fabricating a semiconductor device using a plasma processing apparatus according to one or more exemplary embodiments; and

FIG. 22 is a flowchart illustrating in detail a plasma process performing step of FIG. 21.

### DETAILED DESCRIPTION OF EXEMPLARY EMBODIMENTS

Hereinafter, it is understood that expressions such as “at least one of,” when preceding a list of elements, modify the entire list of elements and do not modify the individual elements of the list.

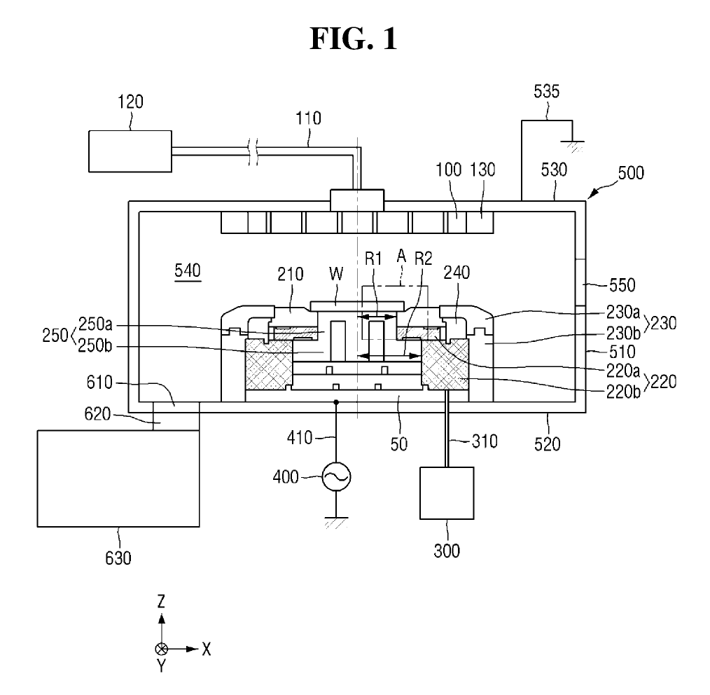

A plasma processing apparatus according to exemplary embodiments will now be described with reference to FIGS. 1 to 7.

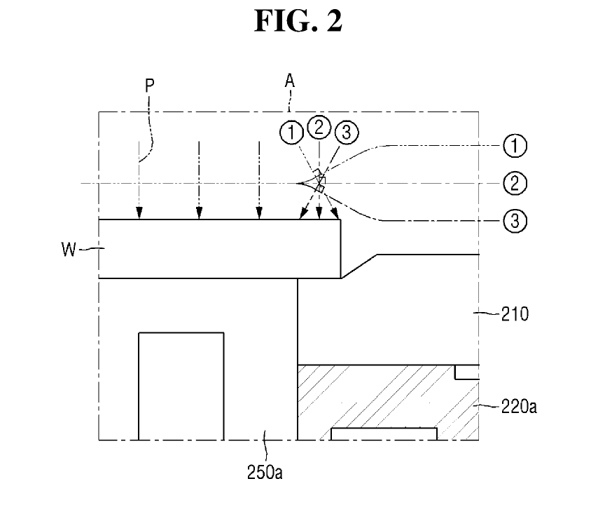

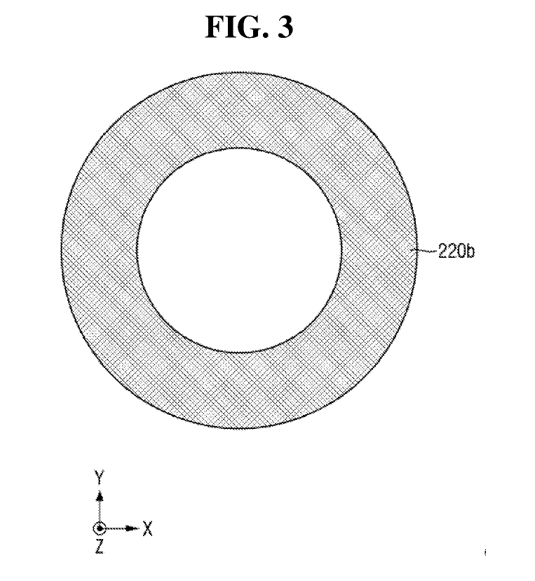

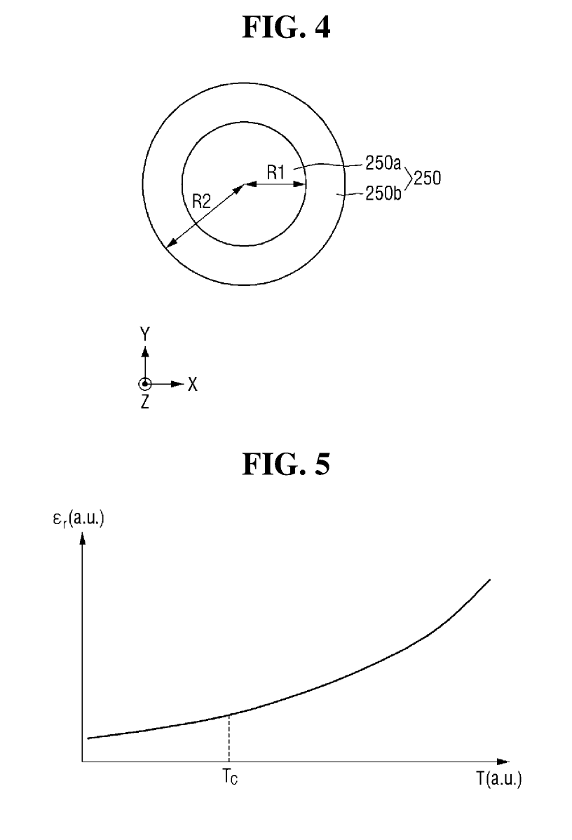

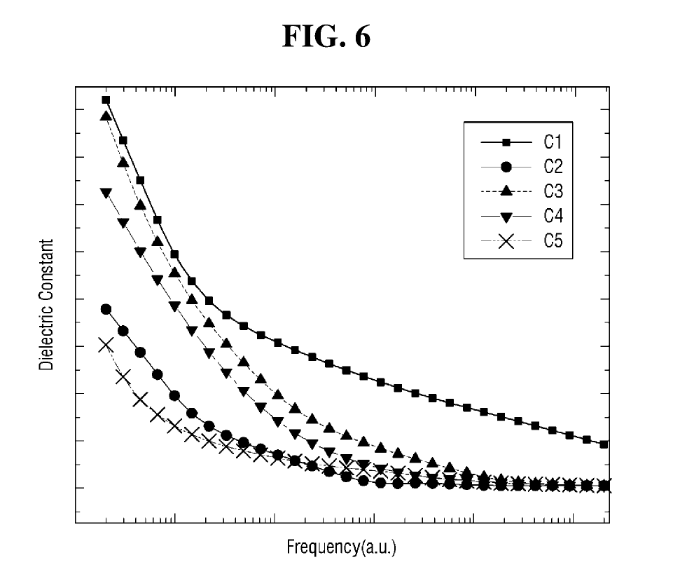

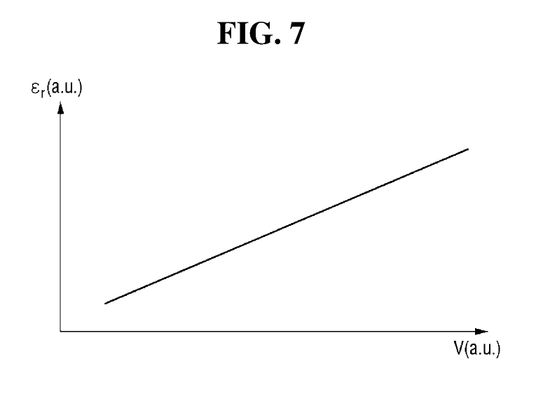

FIG. 1 is a conceptual view illustrating a plasma processing apparatus according to one or more exemplary embodiments. FIG. 2 is a view illustrating an incident direction of a plasma of portion A in the plasma processing apparatus of FIG. 1. FIG. 3 is a plan view illustrating in detail a dielectric ring of FIG. 1. FIG. 4 is a plan view illustrating in detail a chuck stage of FIG. 1. FIG. 5 is a graph for explaining a change in dielectric constant of a material of the dielectric ring of FIG. 1 according to the temperature. FIG. 6 is a graph for explaining a change in dielectric constant of the material of the dielectric ring of FIG. 1 according to the frequency. FIG. 7 is a graph for explaining a change in dielectric constant of the material of the dielectric ring of FIG. 1 according to the voltage.

Referring to FIG. 1, a plasma processing apparatus according to one or more exemplary embodiments includes a chamber 500, a base 50, a chuck stage 250, a gas feeder 100, a dielectric ring 220, a first dielectric constant controller 300, etc.

The chamber 500 may serve as a housing including other components therein. For example, the chamber 500 may include a cavity 540 therein, and the chuck stage 250, the gas feeder 100, and the dielectric ring 220 may be formed in the cavity 540.

The chamber 500 may be a kind of isolated space in which a plasma process is performed on a wafer W. As the chamber 500 is isolated from the outside, processing conditions of the plasma process can be adjusted. Specifically, processing conditions such as at least one of a temperature, pressure, etc., in the chamber can be adjusted differently from the outside.

The chamber 500 may include a chamber bottom 520, a chamber sidewall 510, and a chamber ceiling 530. The cavity 540 may be defined by the chamber bottom 520, the chamber sidewall 510, and the chamber ceiling 530. That is, the cavity 540 may be surrounded by the chamber bottom 520, the chamber sidewall 510, and the chamber ceiling 530.

The chamber bottom 520 may be a bottom surface of the chamber 500. The chamber bottom 520 may support the chuck stage 250 and the like located inside the chamber 500. The chamber bottom 520 may include an outlet 610. The outlet 610 may be a hole for discharging a gas used for a plasma inside the chamber.

The chamber sidewall 510 may be a sidewall of the chamber 500. A planar shape of the chamber sidewall 510 when viewed from a third direction Z may vary. For example, the planar shape of the chamber sidewall 510 may be a circle, an ellipse, a rectangle, and other polygons. However, it is understood that one or more other exemplary embodiments are not limited thereto. In particular, the shape of the chamber sidewall 510 is not limited as long as it can isolate the cavity 540 from the outside.

The chamber sidewall 510 may include an opening 550. The opening 550 may be a hole through which the wafer W can enter and exit. That is, the wafer W may be moved from the outside into the chamber 500 through the opening 550. After the plasma process is completed, the wafer W may be moved to the outside of the chamber 500 through the opening 550, and subjected to a subsequent process.

Although only one opening 550 is shown in FIG. 1, it is understood that one or more other exemplary embodiments are not limited thereto. That is, in one or more other exemplary embodiments, a plurality of openings 550 may be provided. In this case, the openings 550 used for the entrance and exit of the wafer W may vary (e.g., by design) according to the process sequence and the location of the apparatus.

The opening 550 may be closed when the outlet 610 for discharging the gas used for the plasma is opened and a vacuum module 630 (e.g., vacuum or vacuum device) is operated. This is because all the passages other than the outlet 610 are to be closed for the discharge of the gas used for the plasma.

The base 50 may be fixed on the chamber bottom 520 of the chamber 500. The base 50 may support the chuck stage 250 disposed thereon.

The chuck stage 250 may support the wafer W. The chuck stage 250 may be fixed on the base 50. The chuck stage 250 may have a circular planar shape for supporting the circular wafer W, but is not limited thereto in one or more other exemplary embodiments. That is, the planar shape of the chuck stage 250 may be changed or may vary when the shape of the wafer W is changed or for other reasons.

The chuck stage 250 may move in at least one of a first direction X, a second direction Y, and the third direction Z. Accordingly, the chuck stage 250 can adjust the processing position of the wafer W. That is, in order to adjust the plasma processing position of the wafer W, the chuck stage 250 may move in three axes as described above.

The gas feeder 100 may be fixed to the chamber ceiling 530 of the chamber 500. The gas feeder 100 may be located on the chuck stage 250. The gas feeder 100 may supply a gas toward the upper surface of the wafer W placed on the upper surface of the chuck stage 250.

The plasma process may include dry etching the upper surface of the wafer W using a gas plasma. Accordingly, the gas used for the plasma may be supplied into the chamber 500 by the gas feeder 100.

A gas supply line 110 may be connected to the gas feeder 100. The gas supply line 110 may be connected to the chamber ceiling 530 to be externally connected to the gas feeder 100. The gas supply line 110 may be externally connected to a gas source 120 to supply the gas used for the plasma into the chamber 500. However, the position of the gas supply line 110 is not limited to the chamber ceiling 530. That is, according to one or more other exemplary embodiments, the position of the gas supply line 110 may vary depending on the structure and position of the chamber 500 and the position of the gas source 120.

The gas source 120 may store the gas used for plasma generation, and may provide the gas used for the plasma to the chamber 500 during the plasma process. Although FIG. 1 shows the gas source 120 supplying a gas from the outside of the chamber 500 through the gas supply line 110, in a plasma processing apparatus according to one or more other exemplary embodiments, the gas source 120 may be attached directly to the chamber 500.

The gas feeder 100 may supply a gas used for plasma generation into the chamber 500 using a plurality of nozzles. However, it is understood that one or more other exemplary embodiments are not limited thereto.

The gas feeder 100 may serve as an upper electrode for the plasma process. The chuck stage 250 and the base 50 may serve as a lower electrode for the plasma process. The chuck stage 250 and the base 50 may be connected to a first RF power source 400 through a first line 410. The gas feeder 100 may be grounded via a second line 535.

The first RF power source 400 may provide a bias voltage for the plasma process. Accordingly, the plasma can reach the upper surface of the wafer W by the formation of an electric field. Since the plasma contains ionized particles having electric charges, the plasma may proceed in a desired direction (e.g., vertical direction) by the formation of the electric field.

A gas feeder dielectric ring 130 may include a dielectric. The gas feeder dielectric ring 130 may surround a side surface of the gas feeder 100. The gas feeder dielectric ring 130 may overlap the dielectric ring 220, particularly a second dielectric ring 220b in the third direction Z. However, it is understood that one or more other exemplary embodiments are not limited thereto. The gas feeder dielectric ring 130 may also overlap a focus ring 210 or a first dielectric ring 220a in the third direction Z.

The outlet 610 may be located at one side of the chamber 500. Although FIG. 1 illustrates that the outlet 610 is formed in the chamber bottom 520 of the chamber 500, it is understood that one or more other exemplary embodiments are not limited thereto. The outlet 610 may be formed in any of the chamber bottom 520, the chamber sidewall 510, and the chamber ceiling 530 of the chamber 500.

The outlet 610 may be a hole through which the gas used for the plasma is discharged when the plasma process is completed. While the gas used for the plasma is discharged through the outlet 610, the opening 550 through which the wafer W enters and exits may be closed.

The outlet 610 may be connected to a suction port 620. The suction port 620 may be a passage through which the gas used for the plasma discharged by the outlet 610 moves to the vacuum module 630. The suction port 620 may be connected to the vacuum module 630. In a plasma processing apparatus according to one or more exemplary embodiments, the suction port may be omitted, and the vacuum module 630 and the outlet 610 may be in direct contact with each other.

The vacuum module 630 may suck the gas used for the plasma in the chamber 500. The vacuum module 630 may provide a vacuum pressure into the sealed chamber 500 to remove the gas used for the plasma in the chamber 500. The outlet 610 may be closed to isolate the chamber 500 from the suction port 620 after the vacuum module 630 has sucked all the gas used for the plasma.

The dielectric ring 220 may be located on the side surface of the chuck stage 250. The dielectric ring 220 may surround the side surface of the chuck stage 250. The dielectric ring 220 may include the first dielectric ring 220a surrounding an upper portion 250a of the chuck stage 250 and the second dielectric ring 220b surrounding a lower portion 250b of the chuck stage 250. The focus ring 210 surrounding the upper portion 250a of the chuck stage 250 may be positioned on the dielectric ring 220.

The focus ring 210 may also contact the side surface of the wafer W. The focus ring 210 may include a conductor. The focus ring 210 may be disposed to prevent the wafer W from deviating and adjust the potential for plasma injection.

An incidence angle of the plasma injected onto an edge portion of the wafer W will now be described with reference to FIG. 2.

Referring to FIG. 2, a plasma P is basically injected perpendicularly to the upper surface of the wafer W. This is because the potential formed on the wafer W is flat. That is, an equipotential surface may be represented as \textcircled{1}, \textcircled{2} and \textcircled{3} in FIG. 2.

The potential may be kept flat at a central portion of the wafer W, but may not be flat at the edge portion of the wafer W. That is, the potential may be warped depending on the shape, thickness, and material of the focus ring. For this reason, when the potential is increased at the edge portion as indicated by \textcircled{1}, the plasma P may be incident while being inclined toward the outer side of the wafer by the increased potential.

If the potential is also kept flat at the edge portion of the wafer W due to a certain factor as indicated by \textcircled{2}, similarly to the other portions, the plasma P may be incident perpendicularly to the upper surface of the wafer W.

On the other hand, when the potential is lowered at the edge portion of the wafer W as indicated by \textcircled{3}, the plasma P may be incident while being inclined toward the inner side of the wafer W.

At least one of the shape and thickness of the focus ring 210 may be modified by abrasion as the plasma process is repeatedly performed. Accordingly, the incidence angle of the plasma P may be gradually changed in a direction from \textcircled{1} and \textcircled{2} to \textcircled{3}.

As the slope of the incidence angle of the plasma P increases, the distribution of the etch rate of the wafer W becomes non-uniform depending on the position on the upper surface of the wafer W. Thus, the reliability and performance of the semiconductor device formed on the wafer W may be degraded.

Due to such a modification, in a related art plasma processing apparatus, the focus ring 210 should be periodically replaced with a new one. In order to increase the lifetime of the focus ring 210, the basic potential may be set such that the incidence angle of the plasma P is inclined outward as in the case of \textcircled{1} rather than \textcircled{2}, and the focus ring may be replaced when the incidence angle of the plasma P is a critical value after the incidence angle of the plasma P is inclined toward the inner side of the wafer W as in the case of \textcircled{3}.

Accordingly, since the incidence angle of the plasma P at the edge portion of the wafer W changes slightly but continuously as the plasma process is repeatedly performed, the reliability of the process and the uniformity of the semiconductor device are inevitably lowered.

On the other hand, the plasma processing apparatus according to one or more exemplary embodiments includes the dielectric ring 220 for adjusting a dielectric constant in real time, so that the incidence angle of the plasma P at the edge portion of the wafer W can be maintained uniformly.

Referring to FIGS. 1 to 4, the dielectric ring 220 may include the first dielectric ring 220a and a second dielectric ring 220b.

The first dielectric ring 220a may be located below the focus ring 210. The first dielectric ring 220a may surround the periphery of the upper portion 250a of the chuck stage 250.

Referring to FIG. 4, the chuck stage 250 includes the upper portion 250a and the lower portion 250b. The upper portion 250a may have a circular cross section having a first radius R1. The lower portion 250b may be connected to the bottom of the upper portion 250a and have a circular cross section having a second radius R2 greater than the first radius R1. That is, the upper portion 250a may protrude from the lower portion 250b.

Although FIG. 4 illustrates that both the upper portion 250a and the lower portion 250b of the chuck stage 250 have a circular cross section, it is understood that one or more other exemplary embodiments are not limited thereto. For example, the chuck stage 250 is not limited in shape as long as the lower portion 250b has a larger area than the upper portion 250a. That is, the chuck stage 250 may have any shape as long as the upper portion 250a protrudes from the upper surface of the lower portion 250b.

Referring again to FIG. 1, the first dielectric ring 220a may be disposed to surround the side surface of the upper portion of the chuck stage 250. The first dielectric ring 220a may be in contact with only a part of the side surface of the upper portion of the chuck stage 250. The remaining part may be in contact with the focus ring 210.

The first dielectric ring 220a may include a dielectric. For example, the first dielectric ring 220a may include at least one of aluminum oxide (Al₂O₃), aluminum nitride (AlN), polyethylene terephthalate (PETE), and polyetheretherketone (PEEK).

The lower surface of the first dielectric ring 220a may be in contact with the upper surface of the lower portion 250b of the chuck stage 250. A part of the lower surface of the first dielectric ring 220a may be in contact with the upper surface of the lower portion of the chuck stage 250 and the remaining part may not be in contact with the upper surface of the lower portion of the chuck stage 250. The remaining part may be in contact with the second dielectric ring 220b.

Referring to FIGS. 1 and 3, the second dielectric ring 220b may surround the side surface of the lower portion 250b of the chuck stage 250. The lower portion of the second dielectric ring 220b may be in contact with the upper surface of the base 50 and may be connected to the first dielectric constant controller 300 through the base 50. Specifically, the second dielectric ring 220b may be connected to the first dielectric constant controller 300 through a first control line 310 formed in the base 50.

The second dielectric ring 220b may be circular to surround the lower portion of the circular chuck stage 250. The upper surface of the second dielectric ring 220b may be in contact with the lower surface of the first dielectric ring 220a. The dielectric constant of the second dielectric ring 220b may be adjustable in real time by the first dielectric constant controller 300.

The second dielectric ring 220b may include a paraelectric material. The paraelectric material refers to a material that is polarized when a voltage is applied and is not polarized when a voltage is not applied. In contrast, a ferroelectric material is a material that maintains polarization even when no voltage is applied.

The paraelectric material is generally in an amorphous state, and the ferroelectric material is generally in a crystalline state (though not always). The dielectric constant of the paraelectric material is about 2 to 50 and the dielectric constant of the ferroelectric material may be up to 5,000.

The dielectric constant of the ferroelectric material has hysteresis characteristics in accordance with a changing factor such as a voltage. That is, the corresponding dielectric constant may vary depending on whether the changing factor increases or decreases.

On the other hand, the paraelectric material may have a constant dielectric constant in accordance with a certain changing factor without having hysteresis characteristics. Accordingly, it may be easy to adjust the dielectric constant.

Some ferroelectric materials may be phase-changed into paraelectric materials while changing from a crystalline state to an amorphous state at a temperature above a Curie temperature.

The second dielectric ring 220b may include barium titanate (BaTiO₃) (BTO) as the paraelectric material. BTO has a Curie temperature of 120 to 130° C. Thus, BTO can be applied to the paraelectric material at a temperature above the Curie temperature. Accordingly, the temperature of the second dielectric ring 220b can be adjusted to a temperature above the Curie temperature by the first dielectric constant controller 300. However, it is understood that one or more other exemplary embodiments are not limited thereto. The temperature of the second dielectric ring 220b may be maintained above the Curie temperature by an element other than the first dielectric constant controller 300.

BTO has a perovskite structure made of alkaline earth metal (Group 2) elements, and has ferroelectric properties at a temperature below the Curie temperature. The crystal structure changes at the Curie temperature, and thus electrical characteristics (e.g., ferroelectric/paraelectric properties, dielectric constant) may also be changed.

The second dielectric ring 220b may include Ta instead of Ba.

Alternatively, the second dielectric ring 220b may include BiFeO₃ (BFO) or barium strontium titanate (Ba₁₋ₓSrₓTiO₃) (BST) as the paraelectric material.

Referring to FIG. 5, the paraelectric material included in the second dielectric ring 220b may have a paraelectric property at a temperature above a Curie temperature Tc. That is, as the temperature increases, the dielectric constant may tend to increase.

Referring to FIG. 6, when an alternating current (AC) voltage is applied to the paraelectric material, the paraelectric material may change its dielectric constant depending on the frequency. FIG. 6 shows the dielectric constant of the paraelectric material doped with Mo according to the concentration of Mo. C1 is an undoped paraelectric material, and C2, C3, C4 and C5 are paraelectric materials with doping concentrations which increase sequentially.

In FIG. 6, the higher the doping concentration, the higher the dielectric constant. Also, it can be seen that as the frequency of the AC voltage increases, the dielectric constant of the paraelectric material decreases.

Referring to FIG. 7, when a direct current (DC) voltage is applied to the paraelectric material, the paraelectric material may change its dielectric constant depending on the voltage. That is, as the applied voltage increases, the dielectric constant of the paraelectric material may increase.

Referring again to FIG. 1, the dielectric constant of the second dielectric ring 220b may vary in real time through the paraelectric material. The first dielectric constant controller 300 may control the dielectric constant of the second dielectric ring 220b while changing at least one of the temperature, the frequency of an AC power source, and the magnitude of the voltage of a DC power source. The first dielectric constant controller 300 may be implemented by at least one hardware processor and/or memory storing instructions executable by at least one hardware processor.

As the dielectric constant of the second dielectric ring 220b is changed, the capacitance between the focus ring 210 and the base 50 may be changed. The change of the capacitance may change the potential for plasma injection of FIG. 2 described above. As a result, the potential of the edge portion of the wafer W can be flattened by the change of the dielectric constant of the second dielectric ring 220b. Accordingly, the plasma processing apparatus according to one or more exemplary embodiments can correct the incidence angle of the plasma at the edge portion of the wafer W to be perpendicular to the upper surface of the wafer W. Therefore, the overall etch rate distribution on the upper surface of the wafer can be uniformly formed.

A supporting ring 240 may be located on the second dielectric ring 220b. The supporting ring 240 may surround the outer surfaces of the first dielectric ring 220a and the focus ring 210. The supporting ring 240 may not be in contact with the first dielectric ring 220a, and other components may be disposed therebetween. However, it is understood that one or more other exemplary embodiments are not limited thereto.

The height of the upper surface of the supporting ring 240 may be greater than the height of the upper surface of the first dielectric ring 220a and less than the height of the upper surface of the focus ring 210. However, it is understood that one or more other exemplary embodiments are not limited thereto. For example, the size and arrangement of the supporting ring 240 may vary depending on the arrangement of an outer wall 230, the dielectric ring 220, the focus ring 210, and the like.

The outer wall 230 may surround the chuck stage 250, the base 50, the dielectric ring 220, the focus ring 210, and the supporting ring 240. The outer wall 230 may allow the chuck stage 250, the base 50, the dielectric ring 220, the focus ring 210, and the supporting ring 240 to be located internally, thereby isolating them from the outside.

The outer wall 230 may include a first outer wall 230a and a second outer wall 230b. The first outer wall 230a may be located above the second outer wall 230b. The first outer wall 230a may surround the outer side surface of the focus ring 210 and the upper surface and the outer side surface of the supporting ring 240.

The second outer wall 230b may be coupled with the bottom of the first outer wall 230a. The second outer wall 230b may surround the outer side surface of the base 50 and the outer side surface of the second dielectric ring 220b. Further, the second outer wall 230b may surround a part of the side surface of the supporting ring 240.

However, it is understood that the configurations of the first outer wall 230a and the second outer wall 230b are not limited thereto in one or more other exemplary embodiments. For example, the plasma processing apparatus according to one or more other exemplary embodiments may have an outer wall 230 that is formed differently than the above-described arrangement. That is, if all of the above components are included and can be supported, the configuration and arrangement of the outer wall 230 may vary.

The plasma processing apparatus according to one or more exemplary embodiments can adjust the dielectric constant of the second dielectric ring 220b in real time to control the distribution of the etch rate of the edge portion of the wafer W.

Further, it is also possible to control the etch rate to a desired level while uniformly maintaining the distribution of the etch rate. That is, the etch rate of the edge portion can be made larger or smaller. Thus, the etch rate and the process rate of the entire wafer W can be controlled.

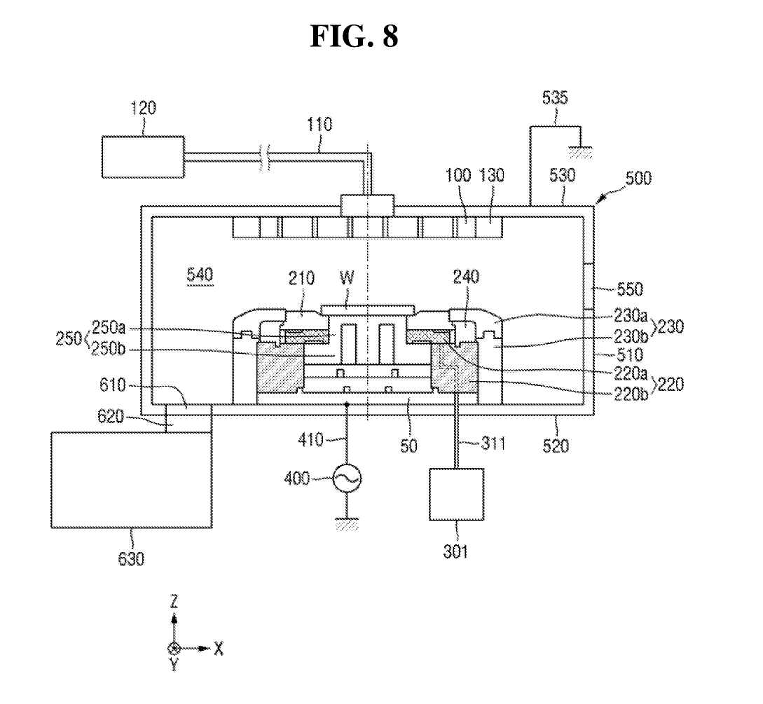

Hereinafter, a plasma processing apparatus according to one or more exemplary embodiments will be described with reference to FIG. 8. A repeated description similar to any description above may be simplified or omitted below.

FIG. 8 is a conceptual diagram illustrating a plasma processing apparatus according to one or more exemplary embodiments.

Referring to FIG. 8, the first dielectric ring 220a of the plasma processing apparatus according to one or more exemplary embodiments may include a paraelectric material. That is, the first dielectric ring 220a may be connected to the first dielectric constant controller 300 to change its dielectric constant.

A second dielectric constant controller 301 may control the dielectric constant of the first dielectric ring 220a by changing at least one of the temperature, voltage and frequency applied to the first dielectric ring 220a. The second dielectric constant controller 301 may be implemented by at least one hardware processor and/or memory storing instructions executable by at least one hardware processor.

A second control line 311 may connect the first dielectric ring 220a to the second dielectric constant controller 301. Although FIG. 8 illustrates the second control line 311 overlapping the second dielectric ring 220b, it is understood that one or more other exemplary embodiments are not limited thereto. That is, the arrangement of the second control line 311 is not limited as long as the second control line 311 is in contact with the first dielectric ring 220a.

The first dielectric ring 220a may be positioned closer to the edge portion of the wafer W while being in direct contact with the lower surface of the focus ring 210. Thus, the potential of the edge portion of the wafer W can be adjusted more precisely. Accordingly, in the plasma processing apparatus according to one or more exemplary embodiments, the correction of the plasma incidence angle at the edge of the wafer W can be performed more precisely.

The second dielectric ring 220b may include a dielectric. The second dielectric ring 220b may include at least one of Al₂O₃, AlN, PETE and PEEK, for example. That is, the second dielectric ring 220b may not include a paraelectric material.

Since the second dielectric ring 220b is located farther away from the wafer W as compared to the first dielectric ring 220a, the ability to control the potential for plasma injection may be relatively insufficient compared to the first dielectric ring 220a. Therefore, by adjusting the dielectric constant of the first dielectric ring 220a instead of the dielectric constant of the second dielectric ring 220b, it is possible to achieve a more substantial effect.

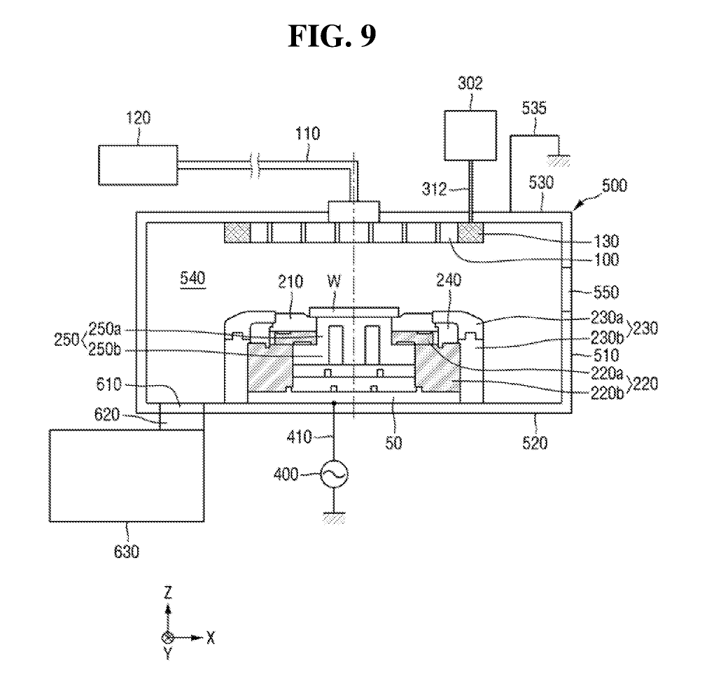

Hereinafter, a plasma processing apparatus according to one or more exemplary embodiments will be described with reference to FIG. 9. A repeated description similar to any description above may be simplified or omitted below.

FIG. 9 is a conceptual diagram illustrating a plasma processing apparatus according to one or more exemplary embodiments.

Referring to FIG. 9, the first dielectric ring 220a of the plasma processing apparatus according to one or more exemplary embodiments may include a dielectric. The first dielectric ring 220a may include at least one of Al₂O₃, AlN, PETE and PEEK, for example. That is, the first dielectric ring 220a may not include a paraelectric material.

The second dielectric ring 220b may include a dielectric. The second dielectric ring 220b may include at least one of Al₂O₃, AlN, PETE and PEEK, for example. That is, the second dielectric ring 220b may not include a paraelectric material.

A gas feeder dielectric ring 130 may include a paraelectric material. That is, the gas feeder dielectric ring 130 may be connected to a third dielectric constant controller 302 to change its dielectric constant. The third dielectric constant controller 302 may control the dielectric constant of the gas feeder dielectric ring 130 by changing at least one of the temperature, voltage, and frequency applied to the gas feeder dielectric ring 130.

A third control line 312 may connect the gas feeder dielectric ring 130 to the third dielectric constant controller 302. The third control line 312 may be connected to the gas feeder dielectric ring 130 through the chamber ceiling 530.

The capacitance between the gas feeder 100 and the focus ring 210 may be adjusted when the dielectric constant of the gas feeder dielectric ring 130 changes. Accordingly, the potential for plasma injection can be adjusted. As a result, the incidence angle of the plasma incident on the edge region of the wafer W can be adjusted.

Further, as the gas feeder dielectric ring 130 includes a paraelectric material, the area over which the gas feeder 100 and the chamber ceiling 530 are grounded through the second line 535 may be reduced. Since a reduction in the grounded area can be adjusted through the dielectric constant, the potential for plasma injection can be adjusted.

The plasma processing apparatus of the present exemplary embodiment can minimize the influence on peripheral components by applying at least one of the temperature, voltage, and frequency to the gas feeder dielectric ring 130 that is relatively spaced apart from other components. Accordingly, it possible to achieve a uniform distribution in the entire process including the edge portion of the wafer W by controlling the dielectric constant of the gas feeder dielectric ring 130 while maintaining a normal operation of other components.

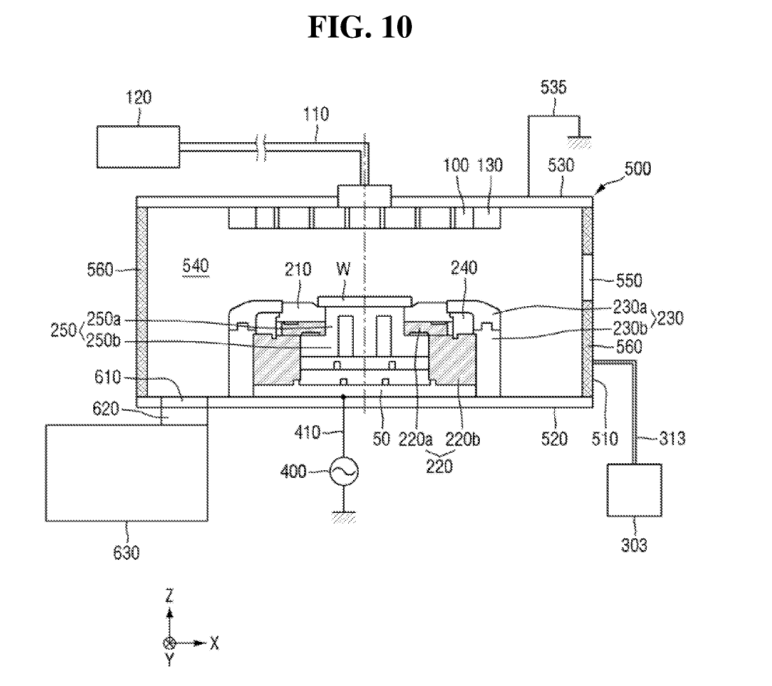

Hereinafter, a plasma processing apparatus according to one or more exemplary embodiments will be described with reference to FIG. 10. A repeated description similar to any description above may be simplified or omitted below.

FIG. 10 is a conceptual diagram illustrating a plasma processing apparatus according to one or more exemplary embodiments.

Referring to FIG. 10, the first dielectric ring 220a of the plasma processing apparatus according to one or more exemplary embodiments may include a dielectric. The first dielectric ring 220a may include at least one of Al₂O₃, AlN, PETE and PEEK, for example. That is, the first dielectric ring 220a may not include a paraelectric material.

The second dielectric ring 220b may include a dielectric. The second dielectric ring 220b may include at least one of Al₂O₃, AlN, PETE and PEEK, for example. That is, the second dielectric ring 220b may not include a paraelectric material.

At least a part of the chamber sidewall 510 may include a chamber sidewall ring 560. The chamber sidewall ring 560 may include a paraelectric material. That is, the chamber sidewall ring 560 may be connected to a fourth dielectric constant controller 303 to change its dielectric constant.

The fourth dielectric constant controller 303 may control the dielectric constant of the chamber side wall ring 560 by changing at least one of the temperature, voltage, and frequency applied to the chamber sidewall ring 560.

A fourth control line 313 may connect the chamber sidewall ring 560 to the fourth dielectric constant controller 303. The fourth control line 313 may be directly connected to the chamber sidewall 510.

As the chamber sidewall ring 560 includes a paraelectric material, the area over which the chamber sidewall 510 and the chamber ceiling 530 are grounded through the second line 535 may be reduced. Since a reduction in the grounded area can be adjusted through the dielectric constant, the potential for plasma injection can be adjusted.

The plasma processing apparatus of the present exemplary embodiment can minimize the influence on peripheral components by applying at least one of the temperature, voltage, and frequency to the chamber sidewall ring 560 that is relatively spaced apart from other components. Accordingly, it possible to achieve a uniform distribution in the entire process including the edge portion of the wafer W by controlling the dielectric constant of the chamber sidewall ring 560 while maintaining a normal operation of other components.

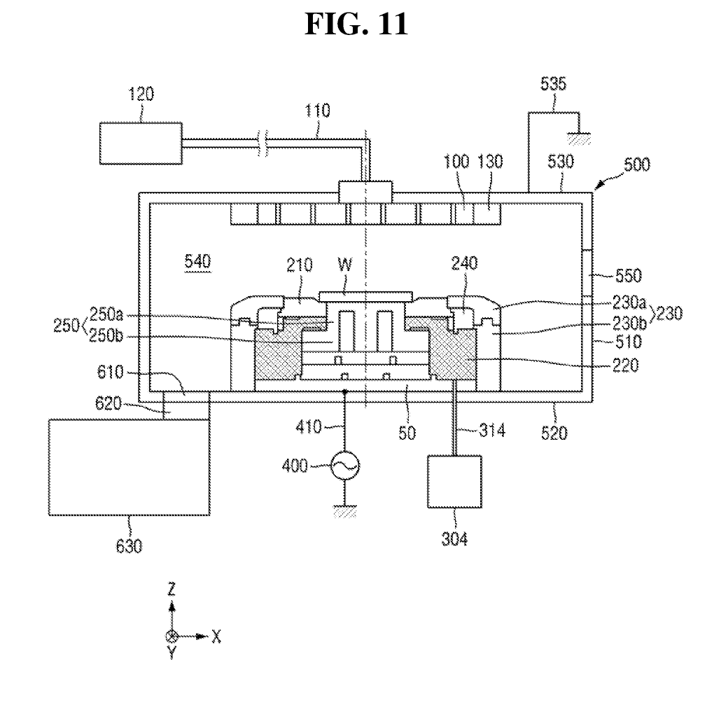

Hereinafter, a plasma processing apparatus according to one or more exemplary embodiments will be described with reference to FIG. 11. A repeated description similar to any description above may be simplified or omitted below.

FIG. 11 is a conceptual diagram illustrating a plasma processing apparatus according to one or more exemplary embodiments.

Referring to FIG. 11, the dielectric ring 220 of the plasma processing apparatus according to one or more exemplary embodiments may include a paraelectric material. That is, the first dielectric ring 220a and the second dielectric ring 220b of FIG. 1 may include the same paraelectric material as one body. The dielectric ring 220 may be connected to a fifth dielectric constant controller 304 to change the dielectric constant of the dielectric ring 220.

The fifth dielectric constant controller 304 may control the dielectric constant of the dielectric ring 220 by changing at least one of the temperature, voltage, and frequency applied to the dielectric ring 220.

A fifth control line 314 may connect the dielectric ring 220 to the fifth dielectric constant controller 304.

The plasma processing apparatus according to the present exemplary embodiment can adjust the capacitance between the base 50 and the focus ring 210 to the greatest extent in order to adjust the potential for plasma injection. Thus, the capacitance can be adjusted within the largest range, and accordingly, the distribution of the wafer W can be adjusted more efficiently.

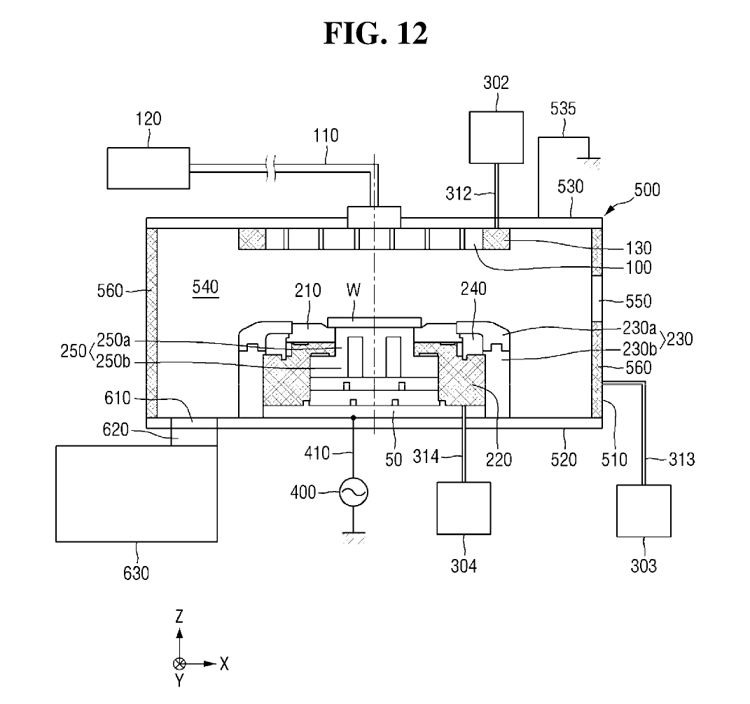

Hereinafter, a plasma processing apparatus according to one or more exemplary embodiments will be described with reference to FIG. 12. A repeated description similar to any description above may be simplified or omitted below.

FIG. 12 is a conceptual diagram illustrating a plasma processing apparatus according to one or more exemplary embodiments.

Referring to FIG. 12, in the plasma processing apparatus according to one or more exemplary embodiments, all of the dielectric ring 220, the gas feeder dielectric ring 130, and the chamber sidewall ring 560 may include a paraelectric material.

Accordingly, by adjusting the capacitance between the base 50 and the focus ring 210, the capacitance between the gas feeder 100 and the focus ring 210, and a reduction in the grounded area of the chamber ground 530 and the chamber sidewall 510, the potential for plasma injection can be adjusted.

Thus, the fifth dielectric constant controller 304, the third dielectric constant controller 302 and the fourth dielectric constant controller 303 can control the dielectric constants of the dielectric ring 220, the gas feeder dielectric ring 130, and the chamber sidewall ring 560 through the fifth control line 314, the third control line 312, and the fourth control line 313, respectively.

Therefore, the plasma processing apparatus of the present exemplary embodiment can exhibit an overlapping effect of the potential adjustment.

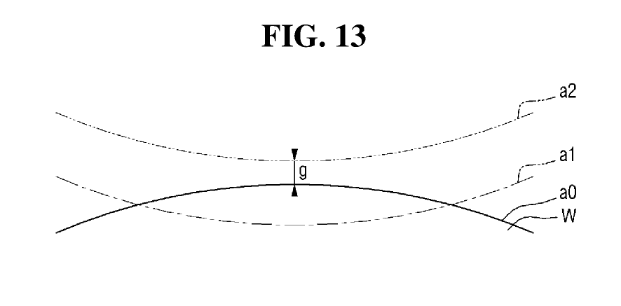

A plasma processing apparatus according to one or more exemplary embodiments may include at least one of the first dielectric ring 220a, the second dielectric ring 220b, the gas feeder dielectric ring 130 and the chamber sidewall ring 560. That is, unlike the exemplary embodiment of FIG. 12, all of the four parts may not include a paraelectric material. The reason will be explained with reference to FIG. 13.

FIG. 13 is a diagram for comparing etch rates of a plasma processing apparatus according to one or more exemplary embodiments.

Referring to FIG. 13, the upper surface of the wafer W may be formed as represented by a0 when the etch rate of the edge portion is excessive and the etch rate of the central portion is insufficient. Accordingly, the upper surface of the wafer W that is flat or inverted (as represented by a1) can be derived by employing an exemplary embodiment of FIGS. 1 and 8 to 12.

However, when the change amount of the capacitance is large, the overall etch rate may be reduced as represented by a2 as compared with a1. In this case, it is possible to provide the wafer W having the upper surface of a2 differently from the upper surface of a1, which is originally intended. Thus, in consideration of the processing conditions, at least one of the first dielectric ring 220a, the second dielectric ring 220b, the gas feeder dielectric ring 130, and the chamber sidewall ring 560 may be selected to include a paraelectric material.

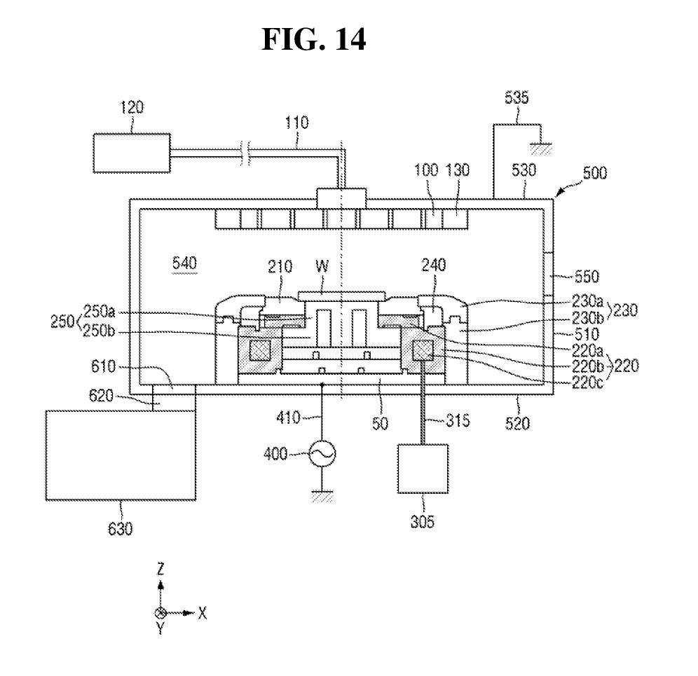

Hereinafter, a plasma processing apparatus according to one or more exemplary embodiments will be described with reference to FIG. 14. A repeated description similar to any description above may be simplified or omitted below.

FIG. 14 is a conceptual diagram illustrating a plasma processing apparatus according to one or more exemplary embodiments.

Referring to FIG. 14, the dielectric ring 220 may include the first dielectric ring 220a, an outer dielectric ring 220b, and an inner dielectric ring 220c.

The second dielectric ring 220b may not include a paraelectric material. The second dielectric ring 220b may surround the inner dielectric ring 220c to protect the inner dielectric ring 220c. The outer dielectric ring 220b may include at least one of Al₂O₃, AlN, PETE and PEEK, for example. However, it is understood that one or more other exemplary embodiments are not limited thereto.

The inner dielectric ring 220c may include a paraelectric material. That is, the internal dielectric ring 220c may be connected to a sixth dielectric constant controller 305 to change its dielectric constant.

The sixth dielectric constant controller 305 may control the dielectric constant of the inner dielectric ring 220c by changing at least one of the temperature, voltage, and frequency applied to the inner dielectric ring 220c.

A sixth control line 315 may connect the inner dielectric ring 220c to the sixth dielectric constant controller 305. Although FIG. 14 illustrates the sixth control line 315 overlapping the outer dielectric ring 220b, it is understood that one or more other exemplary embodiments are not limited thereto. That is, the arrangement of the sixth control line 315 is not limited as long as it is in contact with the inner dielectric ring 220c.

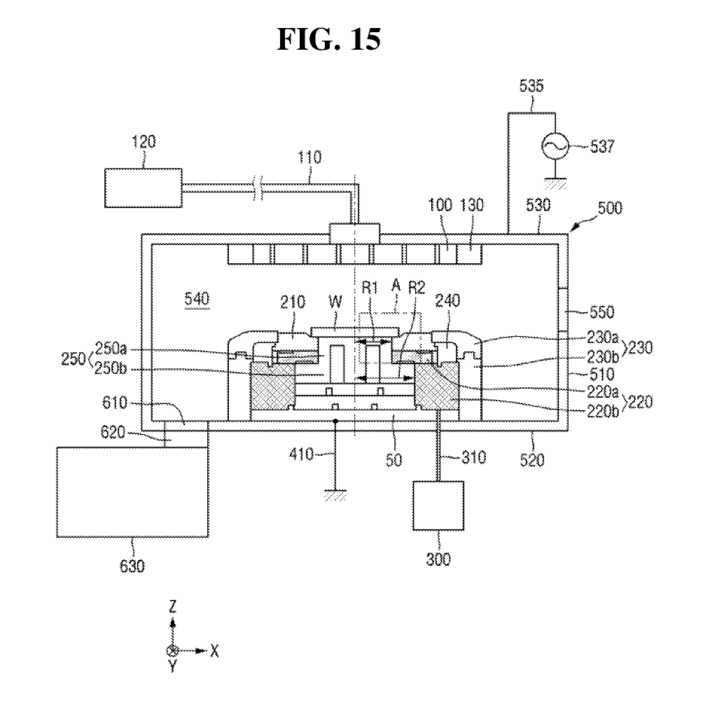

Hereinafter, a plasma processing apparatus according to one or more exemplary embodiments will be described with reference to FIG. 15. A repeated description similar to any description above may be simplified or omitted below.

FIG. 15 is a conceptual diagram illustrating a plasma processing apparatus according to one or more exemplary embodiments.

Referring to FIG. 15, the plasma processing apparatus according to one or more exemplary embodiments may be configured such that the base 50 and the chuck stage 250 serving as a lower electrode are grounded by the first line 410.

Meanwhile, the gas feeder 100 may serve as an upper electrode for a plasma process. The gas feeder 100 may be connected to a second RF power source 537 through the second line 535.

The second RF power source 537 may provide a bias voltage for the plasma process. Accordingly, the plasma can reach the upper surface of the wafer W by the formation of an electric field. Since the plasma contains ionized particles having electric charges, the plasma may proceed in a desired direction (e.g., vertical direction) by the formation of the electric field.

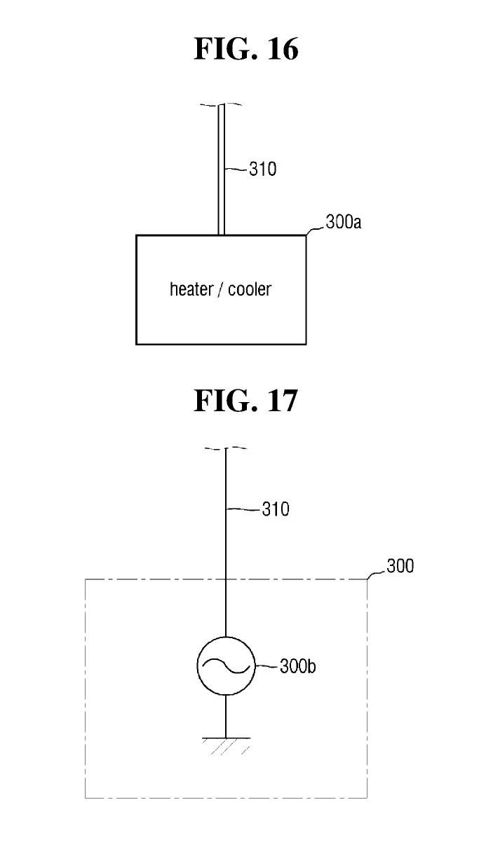

Hereinafter, a plasma processing apparatus according to one or more exemplary embodiments will be described with reference to FIGS. 1 and 16. A repeated description similar to any description above may be simplified or omitted below.

FIG. 16 is a conceptual diagram illustrating in detail a dielectric constant controller of a plasma processing apparatus according to one or more exemplary embodiments.

Referring to FIG. 16, the first dielectric constant controller 300 of the plasma processing apparatus according to one or more exemplary embodiments may include a temperature control device 300a. The first dielectric constant controller 300 may control the temperature of the second dielectric ring 220b through the first control line 310. Accordingly, the temperature of the second dielectric ring 220b can be adjusted and the dielectric constant can be adjusted. As a result, the potential of the edge portion of the wafer W can be adjusted. The first dielectric constant controller 300 and/or the temperature control device 300a may be implemented by at least one hardware processor (e.g., microprocessor or microcontroller) and/or memory storing instructions executable by at least one hardware processor.

The configuration of FIG. 16 can be applied to the second to sixth dielectric constant controllers 301 to 305 of FIGS. 8 to 12 and 14 as a matter of course.

Hereinafter, a plasma processing apparatus according to one or more exemplary embodiments will be described with reference to FIGS. 1 and 17. A repeated description similar to any description above may be simplified or omitted below.

FIG. 17 is a conceptual diagram illustrating in detail a dielectric constant controller of a plasma processing apparatus according to one or more exemplary embodiments.

Referring to FIG. 17, the first dielectric constant controller 300 of the plasma processing apparatus according to one or more exemplary embodiments may include an AC power source 300b. The first dielectric constant controller 300 may adjust the frequency of the AC power source 300b applied to the second dielectric ring 220b through the first control line 310. Accordingly, the dielectric constant of the second dielectric ring 220b can be adjusted. As a result, the potential of the edge portion of the wafer W can be adjusted. The first dielectric constant controller 300 may be implemented by at least one hardware processor (e.g., microprocessor or microcontroller) and/or memory storing instructions executable by at least one hardware processor.

The configuration of FIG. 17 can be applied to the second to sixth dielectric constant controllers 301 to 305 of FIGS. 8 to 12 and 14 as a matter of course.

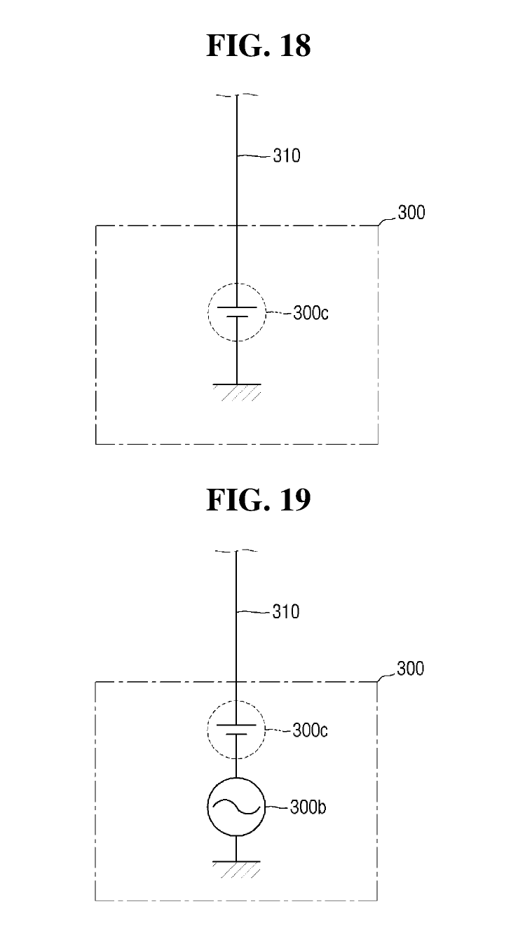

Hereinafter, a plasma processing apparatus according to one or more exemplary embodiments will be described with reference to FIGS. 1 and 18. A repeated description similar to any description above may be simplified or omitted below.

FIG. 18 is a conceptual diagram illustrating in detail a dielectric constant controller of a plasma processing apparatus according to one or more exemplary embodiments.

Referring to FIG. 18, the first dielectric constant controller 300 of the plasma processing apparatus according to one or more exemplary embodiments may include a DC power source 300c. The first dielectric constant controller 300 may adjust the magnitude of the voltage of the DC power source 300c applied to the second dielectric ring 220b through the first control line 310. Accordingly, the dielectric constant of the second dielectric ring 220b can be adjusted. As a result, the potential of the edge portion of the wafer W can be adjusted. The first dielectric constant controller 300 may be implemented by at least one hardware processor (e.g., microprocessor or microcontroller) and/or memory storing instructions executable by at least one hardware processor.

The configuration of FIG. 18 can be applied to the second to sixth dielectric constant controllers 301 to 305 of FIGS. 8 to 12 and 14 as a matter of course.

Hereinafter, a plasma processing apparatus according to one or more exemplary embodiments will be described with reference to FIGS. 1 and 19. A repeated description similar to any description above may be simplified or omitted below.

FIG. 19 is a conceptual diagram illustrating in detail a dielectric constant controller of a plasma processing apparatus according to one or more exemplary embodiments.

Referring to FIG. 19, the first dielectric constant controller 300 of the plasma processing apparatus according to one or more exemplary embodiments may include the DC power source 300c and the AC power source 300b. The DC power source 300c and the AC power source 300b may be connected in series with each other. However, it is understood that one or more other exemplary embodiments are not limited thereto. The plasma processing apparatus may further include other circuit elements such as resistors, coils, and capacitors. The DC power source 300c and the AC power source 300b may be connected in series or in parallel with other circuit elements. As a result, any element that serves to control the dielectric constant of the second dielectric ring 220b through the first control line 310 can be included within the scope of the present disclosure.

The first dielectric constant controller 300 may control the frequency of the AC power source 300b applied to the second dielectric ring 220b and the magnitude of the voltage of the DC power source 300c through the first control line 310. Accordingly, the dielectric constant of the second dielectric ring 220b can be adjusted. As a result, the potential of the edge portion of the wafer W can be adjusted. The first dielectric constant controller 300 may be implemented by at least one hardware processor (e.g., microprocessor or microcontroller) and/or memory storing instructions executable by at least one hardware processor.

The configuration of FIG. 19 can be applied to the second to sixth dielectric constant controllers 301 to 305 of FIGS. 8 to 12 and 14 as a matter of course.

Hereinafter, a plasma processing apparatus according to one or more exemplary embodiments will be described with reference to FIGS. 1 to 20. A repeated description similar any description above may be simplified or omitted below.

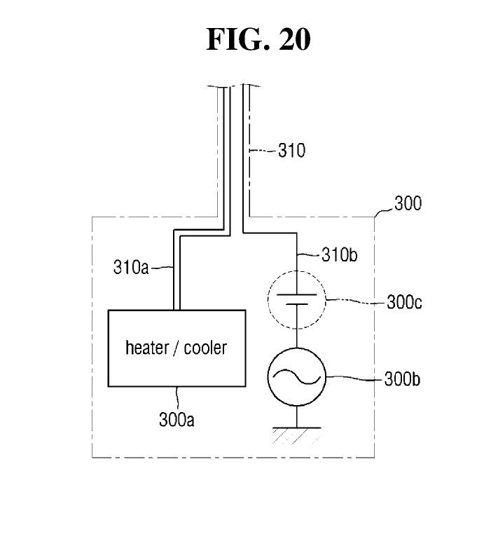

FIG. 20 is a conceptual diagram illustrating in detail a dielectric constant controller of a plasma processing apparatus according to one or more exemplary embodiments.

Referring to FIG. 20, the first dielectric constant controller 300 of the plasma processing apparatus according to one or more exemplary embodiments may include the DC power source 300c, the AC power source 300b, and the temperature control device 300a.

The DC power supply 300c and the AC power supply 300b may be connected in series with each other. However, it is understood that one or more other exemplary embodiments are not limited thereto. The plasma processing apparatus may further include other circuit elements such as resistors, coils, and capacitors. The DC power source 300c and the AC power source 300b may be connected in series or in parallel with other circuit elements.

The temperature control device 300a may be independently connected to the DC power source 300c and the AC power source 300b. That is, the temperature control device 300a may be connected to the second dielectric ring 220b through a temperature control line 310a. The DC power source 300c and the AC power source 300b may be connected to the second dielectric ring 220b through a frequency/voltage control line 310b.

The first control line 310 may include the temperature control line 310a and the frequency/voltage control line 310b.

The first dielectric constant controller 300 may control the frequency of the AC power source 300b applied to the second dielectric ring 220b and the magnitude of the voltage of the DC power source 300c through the frequency/voltage control line 310b. Also, the first dielectric constant controller 300 may control the temperature of the second dielectric ring 220b through the temperature control line 310a. Accordingly, the dielectric constant of the second dielectric ring 220b can be adjusted. As a result, the potential of the edge portion of the wafer W can be adjusted.

Consequently, the dielectric constant can be adjusted by applying at least one of or all of the temperature, frequency, and voltage to the second dielectric ring 220b through the first control line 310. The first dielectric constant controller 300 and/or the temperature control device 300a may be implemented by at least one hardware processor (e.g., microprocessor or microcontroller) and/or memory storing instructions executable by at least one hardware processor.

The configuration of FIG. 20 can be applied to the second to sixth dielectric constant controllers 301 to 305 of FIGS. 8 to 12 and 14 as a matter of course.

Hereinafter, a method for fabricating a semiconductor device according to one or more exemplary embodiments will be described with reference to FIGS. 1, 21 and 22. A repeated description similar any description above may be simplified or omitted below.

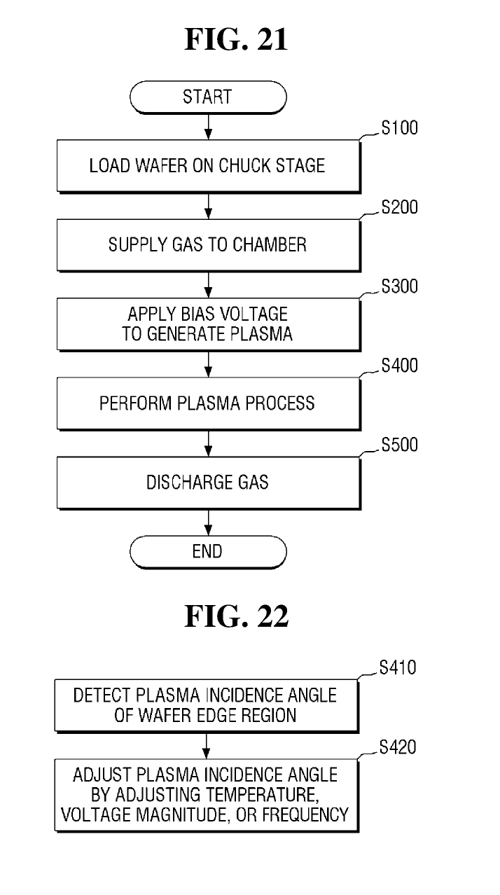

FIG. 21 is a flowchart illustrating a method for fabricating a semiconductor device using a plasma processing apparatus according to one or more exemplary embodiments. FIG. 22 is a flowchart illustrating in detail a plasma process performing step of FIG. 21.

First, referring to FIG. 21, the wafer W is loaded on the chuck stage 250 (operation S100). Specifically, referring to FIG. 1, the wafer W may be transferred into the chamber 500 through the opening 550 provided in the chamber sidewall 510. The wafer W may be placed on the chuck stage 250 located within the chamber 500. The chuck stage 250 may include an upper surface corresponding to the size of the wafer W so that the wafer W is easily loaded.

Then, referring again to FIG. 21, a gas is supplied to the chamber 500 (operation S200).

Specifically, referring to FIG. 1, the wafer W is seated on the chuck stage 250, and the opening 550 may be closed. When the chamber 500 is sealed after the opening 550 is closed or by closing the opening 550 and/or any other opening, a gas for plasma generation may be supplied by the gas feeder 100.

The gas may be supplied from the gas source 120 through the gas supply line 110. The gas feeder 100 may inject the gas into the chamber 500 in the form of a nozzle, but the present disclosure is not limited thereto.

Then, referring again to FIG. 21, a bias voltage is applied to generate a plasma (operation S300).

Specifically, referring to FIG. 1, a bias voltage may be applied to the inside of the chamber 500 through the first RF power source 400, the first line 410, and the grounded second line 535. Accordingly, the electric charges of the gas supplied by the gas feeder 100 may be excited to generate a plasma.

Subsequently, referring again to FIG. 21, a plasma process is performed (operation S400).

The plasma process may include a deposition process, e.g., both a deposition process and an etching process of a layer. This plasma process is performed uniformly in the central portion of the wafer W, but may be performed insufficiently or excessively in the edge portion as compared the central portion. This is caused by a phenomenon in which the incidence angle of the plasma is tilted.

Specifically, referring to FIG. 2, the slope (\textcircled{1}, \textcircled{2}, \textcircled{3}) of the incidence angle of the plasma P is determined according to the distribution (\textcircled{1}, \textcircled{2}, \textcircled{3}) of the potential. Accordingly, the degree of performance of the plasma process at the edge portion of the wafer W may be different from that of the central portion of the wafer W.

In further detail, referring to FIG. 22, first, the plasma incidence angle of the wafer edge region is detected (operation S410).

Then, the plasma incidence angle is adjusted by adjusting at least one of the temperature, voltage magnitude, or frequency (operation S420).

Specifically, referring to FIGS. 1 and 2, the first dielectric constant controller 300 may control at least one of the temperature of the second dielectric ring 220b, the magnitude of the applied voltage, and the frequency of the applied voltage through the first control line 310.

Accordingly, the dielectric constant of the second dielectric ring 220b is adjustable to change the capacitance between the base 50 and the focus ring 210, and the potential can be distributed evenly (\textcircled{2}). In this case, the incidence angle of the plasma P is perpendicular to the potential (\textcircled{2}), so that the plasma process at the edge portion can be performed uniformly as in the central portion.

During the plasma process, the first dielectric constant controller 300 may adjust the dielectric constant of the second dielectric ring 220b in real time. Thus, the plasma process performance of the edge portion of the wafer W can be uniformly maintained during the plasma process.

Referring again to FIG. 21, the plasma process ends and a gas is discharged (operation S400).

Specifically, referring to FIG. 1, the gas in the chamber 500 may be discharged to the outside of the chamber 500 through the outlet 610. The outlet 610 may be connected to the suction port 620 and the vacuum module 630, and the vacuum module 630 may suck the gas using a vacuum pressure.

When the gas is discharged through the outlet 610, the opening 550 may be closed. Thereafter, the wafer W having undergone the plasma process can be transferred through the opening 550. However, one or more other exemplary embodiments are not limited thereto, and the wafer W may further undergo another subsequent process in the chamber 500.

The method for fabricating a semiconductor device according to the present exemplary embodiment can be applied not only to the exemplary embodiment of the plasma processing apparatus of FIG. 1, but also to other exemplary embodiments illustrated in the other drawings of the present specification. Additionally, it is understood that the entirety or at least portions of the method of FIG. 21 and/or the method of FIG. 22 can be implemented under the control of at least one hardware processor executing instructions stored in a memory.

While not restricted thereto, an exemplary embodiment can be embodied as computer-readable code on a computer-readable recording medium. The computer-readable recording medium is any data storage device that can store data that can be thereafter read by a computer system. Examples of the computer-readable recording medium include read-only memory (ROM), random-access memory (RAM), CD-ROMs, magnetic tapes, floppy disks, and optical data storage devices. The computer-readable recording medium can also be distributed over network-coupled computer systems so that the computer-readable code is stored and executed in a distributed fashion. Also, an exemplary embodiment may be written as a computer program transmitted over a computer-readable transmission medium, such as a carrier wave, and received and implemented in general-use or special-purpose digital computers that execute the programs. Moreover, it is understood that in exemplary embodiments, one or more units of the above-described apparatuses can include circuitry, a processor, a microprocessor, etc., and may execute a computer program stored in a computer-readable medium.

It should be understood that exemplary embodiments described herein should be considered in a descriptive sense only and not for purposes of limitation. For example, a single element in the above description may be divided into a plurality of elements, and a plurality of elements in the above description may be combined into a single element. Descriptions of features or aspects within each exemplary embodiment should typically be considered as available for other similar features or aspects in other exemplary embodiments.

While exemplary embodiments have been particularly shown and described with reference to the drawings, it will be understood by those of ordinary skill in the art that various changes in form and details may be made therein without departing from the spirit and scope of the present inventive concept as defined by the following claims. It is therefore desired that disclosed exemplary embodiments be considered in all respects as illustrative and not restrictive, reference being made to the appended claims rather than the foregoing description to indicate the scope of the inventive concept.

1. A plasma processing apparatus comprising:
a chuck stage configured to support a wafer thereon;
a dielectric ring configured to surround a periphery of the chuck stage, the dielectric ring comprising a paraelectric material; and
a dielectric constant controller configured to control a dielectric constant of the dielectric ring.

2. The plasma processing apparatus of claim 1, wherein the dielectric constant controller is configured to control the dielectric constant of the dielectric ring by applying a DC voltage to the dielectric ring and adjusting a magnitude of the applied DC voltage.

3. The plasma processing apparatus of claim 1, wherein the dielectric constant controller is configured to control the dielectric constant of the dielectric ring by applying an AC voltage to the dielectric ring and adjusting a frequency of the applied AC voltage.

4. The plasma processing apparatus of claim 1, wherein the dielectric constant controller is configured to control the dielectric constant of the dielectric ring by applying heat to the dielectric ring to adjust a temperature of the dielectric ring.

5. The plasma processing apparatus of claim 1, further comprising a gas feeder configured to inject a gas onto the chuck stage.

6. The plasma processing apparatus of claim 5, wherein one of the gas feeder and the chuck stage is grounded, and the other one of the gas feeder and the chuck stage is connected to an RF power source.

7. The plasma processing apparatus of claim 1, wherein the dielectric ring comprises an inner dielectric ring having the dielectric constant controlled by the dielectric constant controller, and an outer dielectric ring configured to surround the inner dielectric ring.

8. The plasma processing apparatus of claim 7, wherein:
the inner dielectric ring comprises the paraelectric material; and
the outer dielectric ring comprises at least one of aluminum oxide (Al₂O₃), aluminum nitride (AlN), polyethylene terephthalate (PETE), and polyetheretherketone (PEEK).

9. The plasma processing apparatus of claim 1, wherein the paraelectric material is at least one of barium titanate (BaTiO₃, bismuth ferrite (BiFeO₃), and barium strontium titanate (BST).

10. The plasma processing apparatus of claim 9, wherein a temperature of the dielectric ring is equal to or greater than a Curie temperature of the paraelectric material.

11. A plasma processing apparatus comprising:
a chamber comprising a sidewall;
a chuck stage in the chamber and configured to support a wafer thereon;
a gas feeder in the chamber and configured to supply a gas onto the chuck stage;
a dielectric ring in the chamber and configured to surround the chuck stage or the gas feeder, the dielectric ring including a paraelectric material; and
a dielectric constant controller configured to control a dielectric constant of the dielectric ring.

12. The plasma processing apparatus of claim 11, wherein the dielectric ring surrounds a side surface of the chuck stage.

13. The plasma processing apparatus of claim 12, wherein the chuck stage comprises a lower portion having a first diameter, and an upper portion having a second diameter smaller than the first diameter.

14. The plasma processing apparatus of claim 13, wherein the dielectric ring is in contact with a side surface of the lower portion of the chuck stage.

15. The plasma processing apparatus of claim 13, wherein the dielectric ring is in contact with a side surface of the upper portion of the chuck stage.

16. The plasma processing apparatus of claim 15, further comprising a focus ring on the dielectric ring, the focus ring being in contact with the upper portion of the chuck stage and a side surface of the wafer.

17. The plasma processing apparatus of claim 11, wherein the dielectric ring is a part of the sidewall of the chamber.

18. The plasma processing apparatus of claim 11, wherein the dielectric ring surrounds a side surface of the gas feeder.

19. A plasma processing apparatus comprising:
a chamber comprising a cavity therein;
a chuck stage in the chamber, the chuck stage configured to support a wafer thereon and to which RF power is applied;
a gas feeder in the chamber and configured to supply a gas onto an upper surface of the chuck stage, the gas feeder being grounded;
a first ring configured to surround the chuck stage;
a second ring configured to surround the gas feeder;
a third ring configured to surround the cavity, as a part of a sidewall of the chamber; and
a dielectric constant controller configured to control a dielectric constant of at least one of the first ring, the second ring, and the third ring.

20. The plasma processing apparatus of claim 19, further comprising a gas source connected to the gas feeder and configured to provide the gas used for a plasma.

21-29. (canceled)
